(19) United States
(12) Patent Application Publication
(10) Pub. No.: US 2019/0280052 A1
(43) Pub. Date: Sep. 12, 2019

(54) METHOD FOR MANUFACTURING A TOUCH-CONTROL PANEL AND OLED TOUCH-CONTROL APPARAUTS

(71) Applicant: Wuhan China Star Optoelectronics Semiconductor Display Technology Co., Ltd., Wuhan (CN)

(72) Inventor: Xiaoliang FENG, Shenzhen (CN)

(21) Appl. No.: 16/102,764

(22) Filed: Aug. 14, 2018

Related U.S. Application Data
(63) Continuation of application No. PCT/CN2018/087203, filed on May 17, 2018.

(30) Foreign Application Priority Data
Mar. 12, 2018 (CN) 201810201211.X

(51) Int. Cl. H01L 27/32; G06F 3/041; H01L 51/56; H01L 51/00

(52) U.S. Cl. CPC H01L 27/323; G06F 3/0412; G06F 3/0416; H01L 51/0005; H01L 51/0023; H01L 51/0097; H01L 51/56

(57) ABSTRACT

The present disclosure provides a method for manufacturing a touch-control panel and a display apparatus. According to the method provided in the present disclosure, the touch-control panel may be manufactured under a temperature lower than or equal to 100° C. Therefore, the implementation of the present disclosure may avoid the problem of quality reduction of the touch-control structure due to high temperature, and thus improve the product yield.

### CROSS-REFERENCE TO RELATED APPLICATIONS

The present application is a continuation-application of International (PCT) Patent Application No. PCT/CN2018/087203, filed on May 17, 2018, which claims foreign priority of Chinese Patent Application No. 201810201211.X, filed on Mar. 12, 2018 in the State Intellectual Property Office of China, the entire contents of which are hereby incorporated by reference.

### TECHNICAL FIELD

The present disclosure generally relates to the display technique field, and in particular to a method for manufacturing a touch-control panel and an OLED touch-control display apparatus.

### BACKGROUND

The organic light-emitting diode (OLED) cannot withstand high temperature. Thus, during the manufacturing of the touch-control layer of flexible OLED component, high manufacturing temperature may lead to a quality reduction of the touch-control panel, and thus reduce the product yield.

### SUMMARY

Accordingly, the present disclosure aims to provide a provide a method for manufacturing a touch-control panel and an OLED touch-control display apparatus so as to solve the quality reduction and product yield reduction problem due to the high manufacturing temperature.

To solve the above mentioned problem, a technical scheme adopted by the present disclosure is to provide a method for manufacturing a touch-control panel. The method includes: providing a display panel; forming a first conducting layer on the display panel under a deposition temperature lower than or equal to 100° C.; patterning the first conducting layer under a temperature lower than or equal to 100° C. to form a first patterned conducting layer; forming an insulating layer which covers the first patterned conducting layer under a temperature lower than or equal to 100° C., wherein the insulating layer defines a via hole connecting to the first patterned conducting layer; forming a second conducting layer on the insulating layer under a deposition temperature lower than or equal to 100° C.; and patterning the second conducting layer under a temperature lower than or equal to 100° C. and connecting the second patterned conducting layer with the first patterned connecting layer through the via hole of the insulating layer.

To solve the above mentioned problem, another technical scheme adopted by the present disclosure is to provide a method for manufacturing a touch-control panel. The method includes: providing a display panel; forming a first patterned conducting layer on the display panel under a temperature lower than or equal to 100° C.; forming an insulating layer which covers the first patterned conducting layer under a temperature lower than or equal to 100° C., wherein the insulating layer defines a via hole connecting to the first patterned conducting layer, and forming a second patterned conducting layer on the insulating layer under a temperature lower than or equal to 100° C., wherein the second patterned conducting layer is connected with the first patterned conducting layer though the via hole.

To solve the above mentioned problem, another technical scheme adopted by the present disclosure is to provide an OLED touch-control display apparatus, comprising a touch-control panel with an OLED component, wherein the touch-control panel is manufactured by the above-mentioned method.

By the method of: providing a display panel; forming a first patterned conducting layer on the display panel under a temperature lower than or equal to 100° C.; forming an insulating layer which covers the first patterned conducting layer under a temperature lower than or equal to 100° C., wherein the insulating layer defines a via hole connecting to the first patterned conducting layer, and forming a second patterned conducting layer on the insulating layer under a temperature lower than or equal to 100° C., the first patterned conducting layer and the second patterned conducting layer may be connected together through the via hole and the touch-control panel may be manufactured under a temperature lower than or equal to 100° C. Therefore, the implementation of the present disclosure may avoid the problem of quality reduction of the touch-control panel due to high temperature, and thus improve the product yield.

### BRIEF DESCRIPTION OF THE DRAWINGS

In order to clearly explain the technical solutions in the embodiments of the present disclosure, the drawings used in the description of the embodiments will be briefly described below. Obviously, the drawings in the following description are merely some embodiments of the present disclosure. For those of ordinary skill in the art, other drawings may also be obtained based on these drawings without any creative work.

FIG. 1 is a flow chart of the method for manufacturing a touch-control panel according to an embodiment of the present disclosure.

FIG. 2 shows a schematic diagram of the OLED touch-control apparatus according to an embodiment of the present disclosure.

FIG. 3 shows the sub-blocks of the block S12 of FIG. 1 according to an embodiment of the present disclosure.

FIG. 4 shows the sub-blocks of the block S122 of FIG. 3 according to an embodiment of the present disclosure.

FIG. 5 shows the sub-blocks of the block S13 of FIG. 1 according to an embodiment of the present disclosure.

FIG. 6 shows the sub-blocks of the block S13 of FIG. 1 according to another embodiment of the present disclosure.

FIG. 7 shows the sub-blocks of the block S13 of FIG. 1 according to yet another embodiment of the present disclosure.

FIG. 8 shows the sub-blocks of the block S14 of FIG. 1 according to an embodiment of the present disclosure.

FIG. 9 shows the sub-blocks of the block S142 of FIG. 8 according to an embodiment of the present disclosure.

FIG. 10 shows a schematic diagram of connection between the first patterned conducting layer and the second patterned conducting layer of FIG. 2.

FIG. 11 shows a schematic diagram of the OLED touch-control apparatus according to another embodiment of the present disclosure.

FIG. 12 is a flow chart of the method for manufacturing a touch-control panel according to another embodiment of the present disclosure.

FIG. 13 shows a schematic diagram of the OLED touch-control apparatus according to another embodiment of the present disclosure.

### DETAILED DESCRIPTION

The disclosure will now be described in detail with reference to the accompanying drawings and examples. Apparently, the described embodiments are only a part of the embodiments of the present disclosure, not all of the embodiments. All other embodiments obtained by a person of ordinary skill in the art based on the embodiments of the present invention without creative efforts shall fall within the protection scope of the present invention.

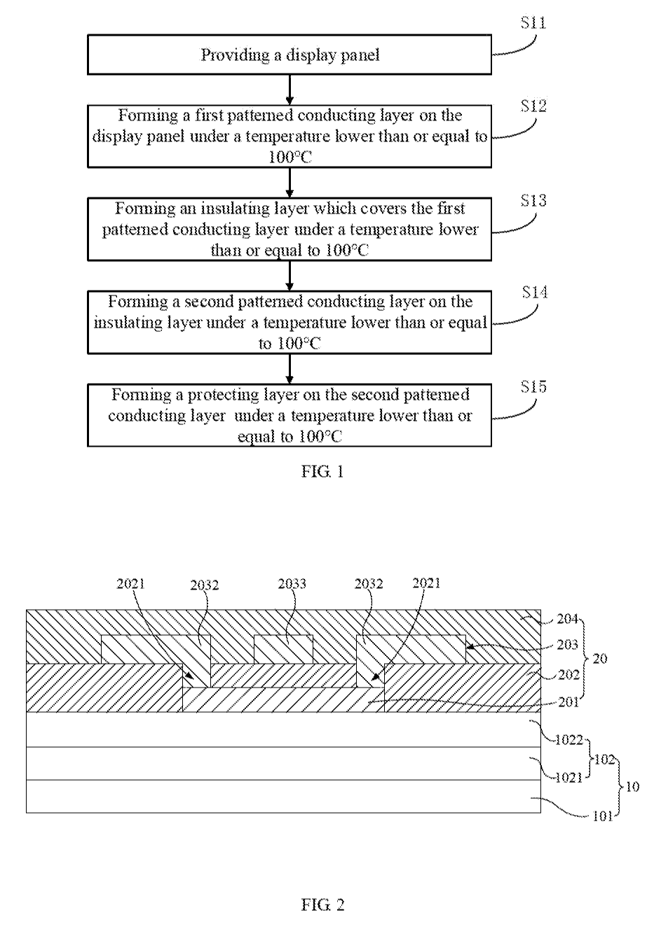

Referring to FIGS. 1 & 2, FIG. 1 is the flow chart of the method for manufacturing the touch-control panel 20 according to an embodiment of the present disclosure. In this embodiment, the method may include the following blocks.

S11: Providing a display panel.

As shown in FIG. 2, the display panel 10 may include a substrate 101 and a display unit 102. The substrate 101 may be a flexible substrate, and may be made of organic material such as polyimide. The display unit 102 may include a thin-film transistor 1021 and an OLED component layer 1022.

The thin film transistor 1021 may be an amorphous-silicon thin-film transistor, thin-film transistor with oxide or low temperature poly-silicon thin-film transistor.

S12: Forming a first patterned conducting layer under a temperature lower than or equal to 100° C.

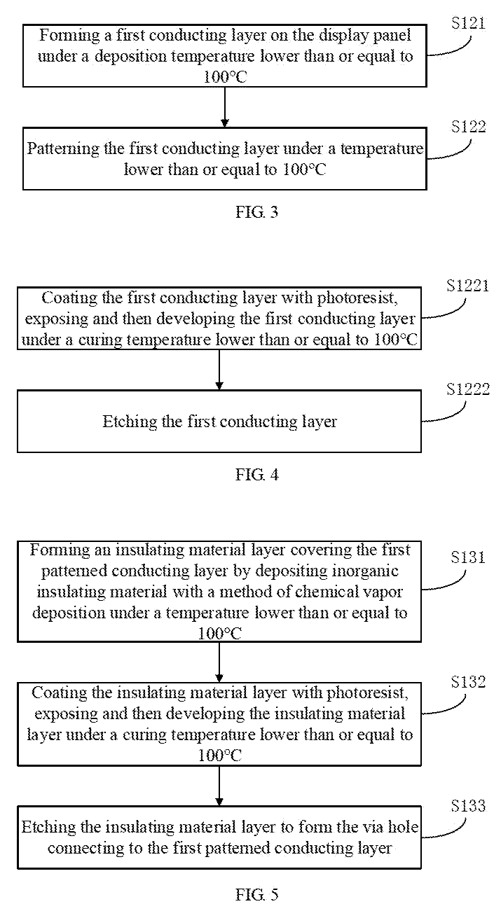

Referring to FIG. 3, the block S12 may specifically include the following sub-blocks.

S121: Forming a first conducting layer on the display panel under a deposition temperature lower than or equal to 100° C.

Specifically, conducting material may be deposited on the OLED component layer 1022 by physical vapor deposition (PVD) so as to form the first conducting layer. The deposition temperature during the PVD process may be configured to be lower than or equal to 100° C.

Optionally, the conducting material may be at least one of, by way of example but not limited to, indium tin oxides (ITO), aluminum, copper, silver, titanium, molybdenum and their alloy.

S122: Patterning the first conducting layer under a temperature lower than or equal to 100° C.

Referring to FIG. 4, the block S122 may specifically include the following sub-blocks.

S1221: Coating the first conducting layer with photoresist, exposing and then developing the photoresist under a temperature lower than or equal to 100° C.

Specifically, the photoresist coating equipment may use spin coating technique. The rotation may make the photoresist agent dropped on the first conducting layer to spread. A photoresist membrane may be formed under the surface tension of the photoresist agent and the centrifugal force. After its formation, the photoresist membrane may be baked under a baking temperature lower than or equal to 100° C. so as to form a dry photoresist membrane, i.e., the photoresist layer.

The photoresist agent may be a photosensitive material which mainly consists of resin, photosensitive agent and solvent.

Furthermore, after the formation of the photoresist layer, the photoresist layer may be exposed under a mask. Then the exposed photoresist layer may be developed with developing solution. Then the photoresist layer may be baked and cured under a baking temperature lower than or equal to 100° C. Thus, the adhesion of the photoresist layer which has been softened and inflated during developing may be strengthened, and the corrosion resistance of the photoresist layer may be improved.

S1222: Etching the first conducting layer.

The first conducting layer may be etched in the sub-block S1222.

Specifically, wet etching with etching liquid may be applied to form the first patterned conducting layer 201. Alternatively, dry etching of the first conducting layer under a temperature lower than or equal to 100° C. may be utilized to form the first patterned conducting layer 201.

S13: Forming an insulating layer which covers the first patterned conducting layer under a temperature lower than or equal to 100° C.

Referring to FIG. 5, the block S13 may specifically include the following sub-blocks.

S131: Forming an insulating material layer covering the first patterned conducting layer by depositing inorganic insulating material with a method of chemical vapor deposition (CVP) under a temperature lower than or equal to 100° C.

Optionally, the insulating material may be at least one of silicon nitride or silicon oxide.

S132: Coating the insulating material layer with photoresist, exposing and then developing the photoresist under a curing temperature lower than or equal to 100° C.

Specifically, the photoresist coating equipment may use spin coating technique. The rotation may make the photoresist agent dropped on the insulating material layer to spread. A photoresist membrane may be formed under the surface tension of the photoresist agent and the centrifugal force. After its formation, the photoresist membrane may be baked under a baking temperature lower than or equal to 100° C. so as to form a dry photoresist membrane, i.e., the photoresist layer.

The photoresist agent may be a photosensitive material which consists of resin, photosensitive agent and solvent.

Furthermore, after the formation of the photoresist layer, the photoresist layer may be exposed under a mask. Then the exposed photoresist layer may be developed with developing solution. Then the photoresist layer may be baked and cured under a baking temperature lower than or equal to 100° C. Thus, the adhesion of the photoresist layer which has been softened and inflated during developing may be strengthened, and the corrosion resistance of the photoresist layer may be improved.

S133: Etching the insulating material layer to form the via hole connecting to the first patterned conducting layer.

The insulating layer may be etched in the sub-block S133. Specifically, wet etching with etching liquid may be applied to form the insulating layer 202 with the via hole 2021. Alternatively, dry etching of the insulating material layer under a temperature lower than or equal to 100° C. may be utilized to form the insulating layer 202 with the via hole 2021.

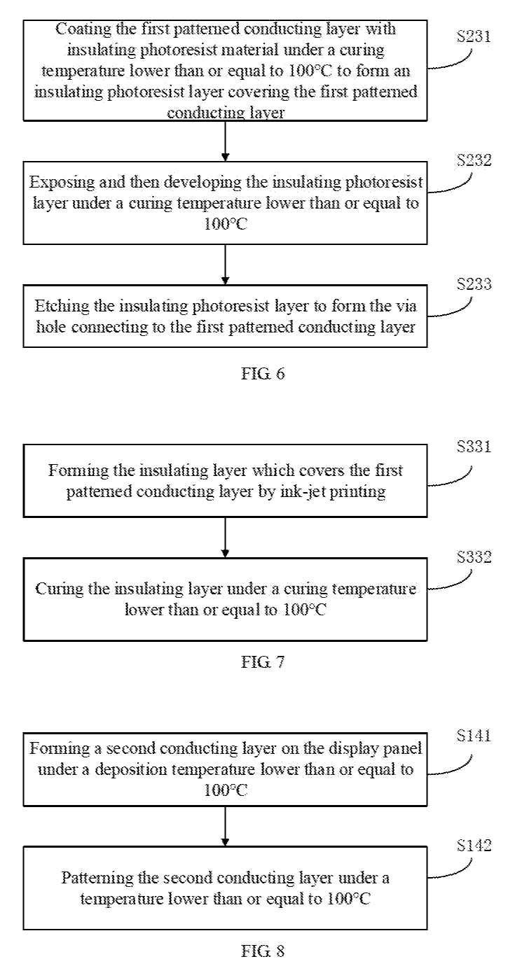

Referring to FIG. 6, in another embodiment, the block S13 may specifically include the following sub-blocks.

S231: Coating the first patterned conducting layer with insulating photoresist material under a curing temperature lower than or equal to 100° C. to form an insulating photoresist layer covering the first patterned conducting layer.

Specifically, the photoresist coating equipment may use spin coating technique to coat and cover the first patterned conducting layer 201 with insulating photoresist material to form the insulating photoresist membrane. After its formation, the insulating photoresist membrane may be baked under a baking temperature lower than or equal to 100° C. so as to form a dry insulating photoresist membrane, i.e., the insulating photoresist layer.

S232: Exposing and then developing the insulating photoresist layer under a curing temperature lower than or equal to 100° C.

Specifically, after the formation of the insulating photoresist layer, the insulating photoresist layer may be exposed under a mask. Then the exposed insulating photoresist layer may be developed with developing solution. Then the insulating photoresist layer may be baked and cured under a baking temperature lower than or equal to 100° C. Thus, the adhesion of the insulating photoresist layer which has been softened and inflated during developing may be strengthened, and the corrosion resistance of the photoresist layer may be improved.

S233: Etching the insulating photoresist layer to form the via hole connecting to the first patterned conducting layer.

The insulating photoresist layer may be etched in the sub-block S233. Specifically, wet etching with etching liquid may be applied to form the insulating layer 202 with the via hole 2021. Alternatively, dry etching of the insulating material layer under a temperature lower than or equal to 100° C. may be utilized to form the insulating layer 202 with the via hole 2021.

In sub-blocks S231 to S233, the insulating photoresist material may be directly coated onto the first patterned conducting layer, then exposed and developed to form the insulating layer 202. Compared with the method of firstly depositing inorganic insulating material and then performing coating, exposing, developing and etching to form the insulating layer 202, this method requires less processing steps. Thus, the embodiment may reduce the cost of the process.

Referring to FIG. 7, in another embodiment, the block S13 may specifically include the following sub-blocks.

S331: Forming the insulating layer which covers the first patterned conducting layer by ink-jet printing.

Specifically, the insulating layer 202 which covers the first patterned conducting layer 201 and defines the via hole 2021 connecting to the first patterned conducting layer 201 may be directly printed out. Thus, the steps of deposition, photoresist coating, exposing, developing and etching may be omitted, and the cost of the process may be reduced.

S332: Curing the insulating layer under a curing temperature lower than or equal to 100° C.

Specifically, after the insulating layer 202 is directly printed out. The insulating layer 202 may be baked and cured under a baking temperature lower than or equal to 100° C. Alternatively, the insulating layer 202 may be cured by light under a light-curing temperature lower than or equal to 100° C.

S14: Forming a second patterned conducting layer on the insulating layer under a temperature lower than or equal to 100° C.

Referring to FIG. 8, the block S14 may specifically include the following sub-blocks.

S141: Forming a second conducting layer on the insulating layer under a temperature lower than or equal to 100° C.

Specifically, the second conducting layer may be formed by depositing conducting material on the insulating layer 202 by physical vapor deposition under a temperature lower than or equal to 100° C.

Optionally, the conducting material may be at least one of, by way of example but not limited to, indium tin oxides (ITO), aluminum, copper, silver, titanium, molybdenum and their alloy.

S142: Patterning the second conducting layer under a temperature lower than or equal to 100° C.

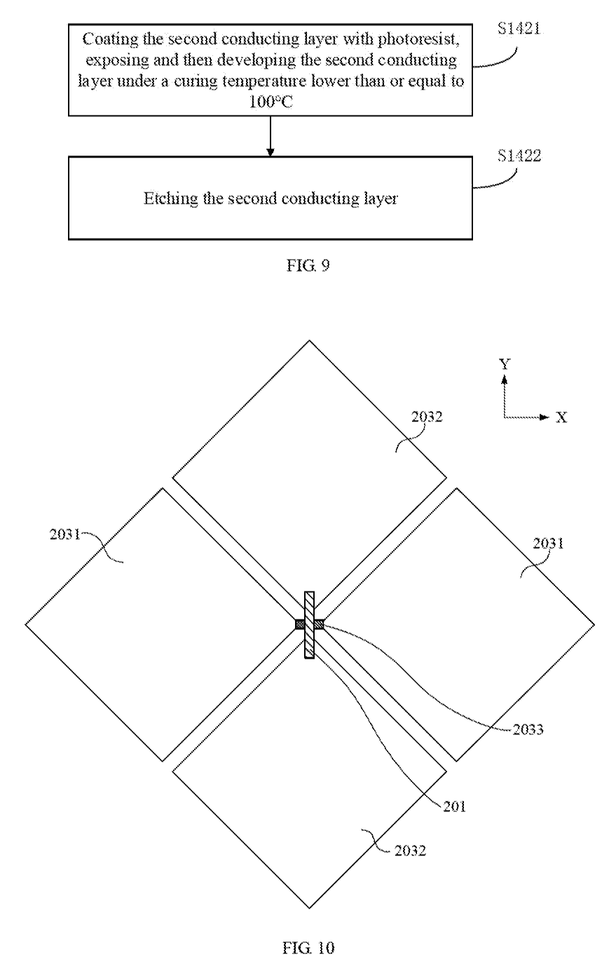

Referring to FIG. 9, the block S142 may include the following sub-blocks.

S1421: Coating the second conducting layer with photoresist, exposing and then developing the photoresist under a curing temperature lower than or equal to 100° C.

Specifically, the photoresist coating equipment may use spin coating technique. The rotation may make the photoresist agent dropped on the second conducting layer to spread. A photoresist membrane may be formed under the surface tension of the photoresist agent and the centrifugal force. After its formation, the photoresist membrane may be baked under a baking temperature lower than or equal to 100° C. so as to form a dry photoresist membrane, i.e., the photoresist layer.

The photoresist agent may be a photosensitive material which consists of resin, photosensitive agent and solvent.

Moreover, after the formation of the photoresist layer, the photoresist layer may be exposed under a mask. Then the exposed photoresist layer may be developed with developing solution. Then the photoresist layer may be baked and cured under a baking temperature lower than or equal to 100° C. Thus, the adhesion of the photoresist layer which has been softened and inflated during developing may be strengthened, and the corrosion resistance of the photoresist layer may be improved.

S1422: Etching the second conducting layer.

The second conducting layer may be etched in the sub-block S1422. Specifically, wet etching with etching liquid may be applied to form the second patterned conducting layer 203. Alternatively, dry etching of the second conducting layer under a temperature lower than or equal to 100° C. may be utilized to form the second patterned conducting layer 201.

Moreover, the second patterned conducting layer 203 may connect to the first patterned conducting layer 201 though the via hole 2021 of the insulating layer 202.

Referring FIGS. 2 & 10, the second patterned conducting layer 203 formed by etching the second conducting layer in block S1422 may include several first patterned conducting sub-layers 2031 arranged along a first direction, several second patterned conducting sub-layers 2032 arranged along a second direction and a patterned connecting layer 2033. In the embodiment of FIG. 10, the first patterned conducting sub-layers 2031 may be arranged along the X direction while the second patterned conducting sub-layers 2032 may be arranged along the Y direction.

The first patterned conducting layer 201 may connect either the first patterned conducting sub-layers 2031 along the first direction or the second patterned conducting sub-layers 2032 along the second direction. The patterned connecting layer 2033 may correspondingly connect either the second patterned conducting sub-layers 2032 long the second direction or the first patterned conducting sub-layers 2031 along the first direction. In the figure of this embodiment, the first patterned conducting layer 201 may connect several second patterned conducting layer 2032 along the Y direction. The patterned connecting layer 2033 may connect several first patterned conducting sub-layers 2031 along the X direction.

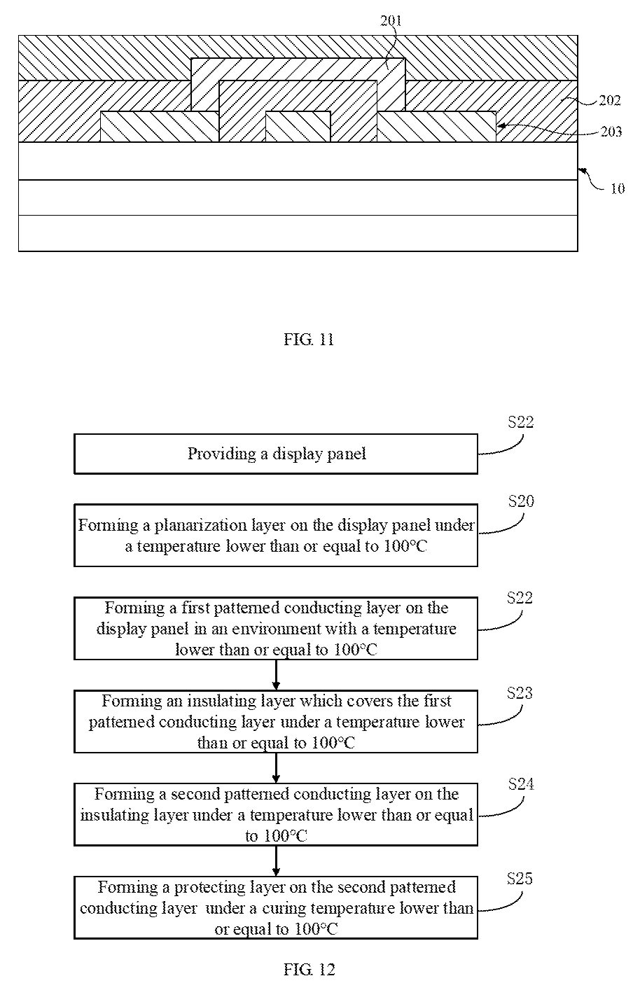

Referring to FIG. 11, in other embodiments, the order to perform the block S14 and S12 may be exchanged. In other word, the second patterned conducting layer 203 may be firstly formed on the display panel 10, and then the first patterned conducting layer 201 connecting to the second patterned conducting layer 203 may be formed on the insulating layer 202. The manufacturing process may be similar with those set forth in above embodiments and will not be described hereon.

Furthermore, the method of this embodiment may further include the following block.

S15: Forming a protecting layer on the second patterned conducting layer under a curing temperature lower than or equal to 100° C.

Specifically, the protecting layer 204 may be formed by coating the second patterned conducting layer 202 with photoresist, exposing and then developing the photoresist by a yellow-light photolithography process under a curing temperature lower than or equal to 100° C. Optionally, the protecting layer 204 may be an organic protecting layer.

In other embodiments, the protecting layer 204 may be printed onto the second patterned conducting layer 203 by ink-jet printing. After being printed out, the protecting layer 204 may be baked and cured under a baking temperature lower than or equal to 100° C. Alternatively, the protecting layer 204 may cured by light under a light-curing temperature lower than or equal to 100° C.

Referring to FIGS. 12 & 13, FIG. 12 shows the flow chart of the method for manufacturing the touch-control panel 30 according to another embodiment of the present disclosure. The blocks S21, S22. S23, S24 and S25 are similar to the blocks S11, S12, S13, S14 and S15 of the above-mentioned embodiments and will not be described hereon. In this embodiment, after the block S21, the method may further include:

S20: Forming a planarization layer on the display panel under a temperature lower than or equal to 100° C.

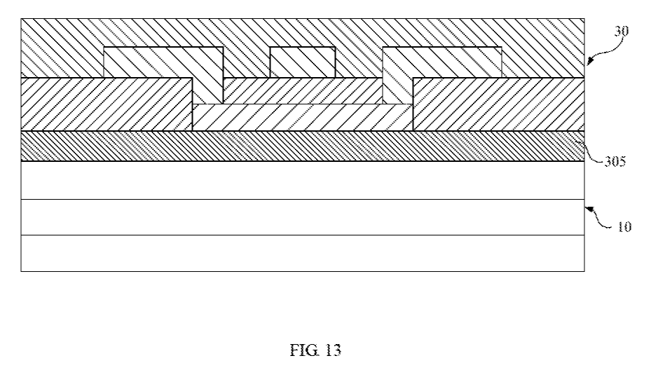

As shown in FIG. 13, the planarization layer 305 may be formed on the display panel 10 by physical vapor deposition. The deposition temperature during the PVD process may be configured to be lower than or equal to 100° C.

Optionally, the planarization layer 305 may be an inorganic planarization layer made of silicon nitride or silicon oxide, or alternative an organic planarization.

Moreover, referring to FIGS. 2 & 13, the present disclosure may further provide an OLED touch-control display apparatus. The apparatus may include a touch-control structure with an OLED component 10.

The touch-control panel may be manufactured according to any one of the above-described embodiments, e.g., the touch-control panel 20 or 30. Detailed description may be found in the above-mentioned embodiments and will not be described hereon.

By the method of: providing a display panel: forming a first patterned conducting layer on the display panel under a temperature lower than or equal to 100° C.; forming an insulating layer which covers the first patterned conducting layer under a temperature lower than or equal to 100° C., wherein the insulating layer defines a via hole connecting to the first patterned conducting layer; and forming a second patterned conducting layer on the insulating layer under a temperature lower than or equal to 100° C., the first patterned conducting layer and the second patterned conducting layer may be connected together through the via hole and the touch-control panel may be manufacturing under a temperature lower than or equal to 100° C. Therefore, the implementation of the present disclosure may avoid the problem of quality reduction of the touch-control panel due to high temperature, and thus improve the product yield.

The foregoing is merely embodiments of the present disclosure, and is not intended to limit the scope of the disclosure. Any transformation of equivalent structure or equivalent process which uses the specification and the accompanying drawings of the present disclosure, or directly or indirectly application in other related technical fields, are likewise included within the scope of the protection of the present disclosure.

What is claimed is:

1. A method for manufacturing a touch-control panel, comprising:
providing a display panel;
forming a first conducting layer on the display panel under a deposition temperature lower than or equal to 100° C.;
patterning the first conducting layer under a temperature lower than or equal to 100° C. to form a first patterned conducting layer;
forming an insulating layer which covers the first patterned conducting layer under a temperature lower than or equal to 100° C., wherein the insulating layer defines a via hole connecting to the first patterned conducting layer;
forming a second conducting layer on the insulating layer under a deposition temperature lower than or equal to 100° C.; and
patterning the second conducting layer under a temperature lower than or equal to 100° C. and connecting the second patterned conducting layer with the first patterned connecting layer through the via hole of the insulating layer.

2. The method of claim 1, wherein the patterning the first conducting layer under a temperature lower than or equal to 100° C. comprises:
coating the first conducting layer with photoresist, exposing and then developing the photoresist under a curing temperature lower than or equal to 100° C.; and
etching the first conducting layer by dry etching or wet etching under an etching temperature lower than or equal to 100° C.

3. The method of claim 1, wherein the forming the insulating layer which covers the first patterned conducting layer under a temperature lower than or equal to 100° C. comprises:
forming an insulating material layer covering the first patterned conducting layer by depositing inorganic insulating material with a method of chemical vapor deposition under a temperature lower than or equal to 100° C.;
coating the insulating material layer with photoresist, exposing and then developing the photoresist under a curing temperature lower than or equal to 100° C.; and
etching the insulating material layer by dry etching or wet etching under an etching temperature lower than or equal to 100° C. to form the via hole connecting to the first patterned conducting layer.

4. The method of claim 1, wherein the forming the insulating layer which covers the first patterned conducting layer under a temperature lower than or equal to 100° C. comprises:
coating the first patterned conducting layer with insulating photoresist material to form an insulating photoresist layer covering the first patterned conducting layer;
exposing and then developing the insulating photoresist material under a curing temperature lower than or equal to 100° C.; and
etching the insulating photoresist layer by dry etching or wet etching under an etching temperature lower than or equal to 100° C. to form the via hole connecting to the first patterned conducting layer.

5. The method of claim 1, wherein the forming the insulating layer which covers the first patterned conducting layer under a temperature lower than or equal to 100° C. comprises:
forming the insulating layer which covers the first patterned conducting layer by ink-jet printing; and
curing the insulating layer under a curing temperature lower than or equal to 100° C.

6. The method of claim 1, wherein the patterning the second conducting layer under a temperature lower than or equal to 100° C. comprises:
coating the second conducting layer with photoresist, exposing and then developing the photoresist under a curing temperature lower than or equal to 100° C.; and
etching the second conducting layer by dry etching or wet etching under an etching temperature lower than or equal to 100° C.

7. The method of claim 1, further comprising:
forming a protecting layer on the second patterned conducting layer under a temperature lower than or equal to 100° C.

8. A method for manufacturing a touch-control panel, comprising:
providing a display panel;
forming a first patterned conducting layer on the display panel under a temperature lower than or equal to 100° C.;
forming an insulating layer which covers the first patterned conducting layer under a temperature lower than or equal to 100° C., wherein the insulating layer defines a via hole connecting to the first patterned conducting layer; and
forming a second patterned conducting layer on the insulating layer under a temperature lower than or equal to 100° C., wherein the second patterned conducting layer is connected with the first patterned conducting layer though the via hole.

9. The method of claim 8, wherein the forming the first patterned conducting layer on the display panel under a temperature lower than or equal to 100° C. comprises:
forming a first conducting layer on the display panel under a deposition temperature lower than or equal to 100° C.; and
patterning the first conducting layer under a temperature lower than or equal to 100° C.

10. The method of claim 9, wherein the patterning the first conducting layer under a temperature lower than or equal to 100° C. comprises:
coating the first conducting layer with photoresist, exposing and then developing the photoresist under a curing temperature lower than or equal to 100° C.; and
etching the first conducting layer by dry etching or wet etching under an etching temperature lower than or equal to 100° C.

11. The method of claim 8, wherein the forming the insulating layer which covers the first patterned conducting layer under a temperature lower than or equal to 100° C. comprises:
forming an insulating material layer covering the first patterned conducting layer by depositing inorganic insulating material with a method of chemical vapor deposition under a temperature lower than or equal to 100° C.;
coating the insulating material layer with photoresist, exposing and then developing the photoresist under a curing temperature lower than or equal to 100° C.; and
etching the insulating material layer by dry etching or wet etching under an etching temperature lower than or equal to 100° C. to form the via hole connecting to the first patterned conducting layer.

12. The method of claim 8, wherein the forming the insulating layer which covers the first patterned conducting layer under a temperature lower than or equal to 100° C. comprises:
coating the first patterned conducting layer with insulating photoresist material under a curing temperature lower than or equal to 100° C. to form an insulating photoresist layer covering the first patterned conducting layer,
exposing and then developing the insulating photoresist layer under a curing temperature lower than or equal to 100° C.; and
etching the insulating photoresist layer by dry etching or wet etching under an etching temperature lower than or equal to 100° C. to form the via hole connecting to the first patterned conducting layer.

13. The method of claim 8, wherein the forming the insulating layer which covers the first patterned conducting layer under a temperature lower than or equal to 100° C. comprises:
forming the insulating layer which covers the first patterned conducting layer by ink-jet printing; and
curing the insulating layer under a curing temperature lower than or equal to 100° C.

14. The method of claim 8, wherein the forming the second patterned conducting layer on the display panel under a temperature lower than or equal to 100° C. comprises:
forming a second conducting layer on the display panel under a deposition temperature lower than or equal to 100° C.; and
patterning the second conducting layer under a temperature lower than or equal to 100° C. and connecting the second patterned conducting layer with the first patterned connecting layer through the via hole of the insulating layer.

15. The method of claim 14, wherein the patterning the second conducting layer under a temperature lower than or equal to 100° C. comprises:
coating the second conducting layer with photoresist, exposing and then developing the photoresist under a curing temperature lower than or equal to 100° C.; and
etching the second conducting layer by dry etching or wet etching under an etching temperature lower than or equal to 100° C.

16. The method of claim 8, further comprising:
forming a protecting layer on the second patterned conducting layer under a temperature lower than or equal to 100° C.

17. An OLED touch-control display apparatus, comprising a touch-control panel with an OLED component, wherein the touch-control panel is manufactured by the above-mentioned method.
